(19) United States
(12) Patent Application Publication
(10) Pub. No.: US 2025/0076939 A1
(43) Pub. Date: Mar. 6, 2025

(54) MEMORY MODULES INCLUDING ACTIVE COOLING DEVICES AND RELATED METHODS

(71) Applicant: SMART Modular Technologies, Inc., Newark, CA (US)

(72) Inventors: Satyanarayan Iyer, Pulau Pinang (MY); Torry Steed, Poway, CA (US); Luis Fukazawa, Dublin, CA (US)

(21) Appl. No.: 18/240,402

(22) Filed: Aug. 31, 2023

(51) Int. Cl. G06F 1/20; H05K 7/20

(52) U.S. Cl. CPC G06F 1/20; H05K 7/20218

(57) ABSTRACT

Memory modules comprise memory chips coupled to a surface of one or more substrates. The memory chips contain large numbers of storage cells that consume power during normal operation, generating heat in the memory chips and causing temperatures to increase. As the temperatures increase, leakage currents can increase in the memory chips, and performance of the memory chips can decrease. A memory module includes memory chips disposed on a substrate and an active cooling device disposed on the substrate to increase the rate at which heat is dissipated to reduce or maintain temperatures and thereby save power and improve performance. In some examples, the active cooling device is disposed on a side of a memory chip opposite to the card in the memory module to improve cooling of the memory chips. In some examples, the active cooling device is a thermoelectric device.

### FIELD OF THE DISCLOSURE

The present disclosure relates to data storage devices that may be employed in computer processing systems.

### BACKGROUND

Technologies for manufacturing the components of computer processing systems have advanced to provide more circuits and, therefore, more functionality in smaller packages. Processors and processing circuits that process data (e.g., in response to executing software instructions) may include many transistor circuits that change state or “switch” in cycles of a system clock. Transistor circuits consume power when they switch and may even consume power when idle (i.e., not switching) due to current leakage. The power consumed by transistor circuits causes heating of the transistor circuits. As processing activity increases, more power is consumed, generating more heat. The heat must be dissipated from the processing circuits to avoid heating the circuits to a temperature at which they can be permanently damaged. As processing circuits become smaller, and more are included in a same volume as technologies advance, more heat is generated in a same space, increasing the need for improved heat dissipation.

### SUMMARY

Aspects disclosed herein include memory modules, including active cooling devices. Related methods of active cooling in a memory module are also disclosed. Memory modules are employed in computer processing systems to store data that may be accessed by or produced in a processing circuit. The data in a memory module is stored in memory chips that are coupled to a surface of one or more substrates, referred to as cards or boards. The memory chips may each contain large numbers of storage cells generating heat in the memory chips and causing temperatures to increase. As the temperatures increase, leakage currents can increase in the memory chips and performance of the memory chips can decrease. In exemplary aspects disclosed herein, a memory module includes memory chips disposed on a substrate and an active cooling device disposed on the substrate to increase the rate at which heat is dissipated to reduce or maintain temperatures and thereby save power and improve performance. In some examples, the active cooling device is disposed on a side of a memory chip opposite to the card in the memory module to improve cooling of the memory chips. In some examples, the active cooling device is a thermoelectric device.

In this regard, in one aspect, a memory module configured to store data is disclosed. The memory module includes at least one substrate and one or more memory chips, each configured to store a portion of the data. The memory module further includes an active cooling device disposed on the substrate.

In this regard, in one aspect, a computer processing system is disclosed. The computer processing system includes a processor circuit configured to process data and a memory module configured to store the data. The memory module includes at least one substrate and one or more memory chips, each configured to store a portion of the data. The memory module further includes an active cooling device disposed on the substrate.

In another aspect, any of the foregoing aspects, individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is an illustration of one example of an active cooling device, in particular a thermoelectric device, also known as a Peltier cooling device;

FIG. 2 is an illustration of a second example of an active cooling device, in particular, a liquid cooling device;

FIG. 3A is an illustration of a first example of an exemplary memory module comprising an active cooling device disposed on a substrate, including memory chips;

FIG. 3B is an illustration of a cross-sectional side view of a region of the memory module in FIG. 3A, showing the active cooling device disposed on the memory chips;

FIG. 4A is an illustration of a second example of an exemplary memory module comprising an active cooling device disposed on a substrate, including memory chips;

FIG. 4B is an illustration of a cross-sectional side view of a region of the memory module in FIG. 4A, showing the active cooling device disposed on the memory chips;

FIG. 5A is an illustration of a third example of an exemplary memory module comprising active cooling devices disposed on a substrate, including memory chips;

FIG. 5B is a cross-sectional side view of a first region of the memory module in FIG. 5A, including a first active cooling device disposed on the memory chips;

FIG. 5C is a cross-sectional side view of a second region of the memory module in FIG. 5A, including a second active cooling device disposed on components of the memory module;

FIG. 6A is an illustration of a fourth example of an exemplary memory module comprising active cooling devices disposed on a substrate, including memory chips;

FIG. 6B is a cross-sectional side view of a first region of the memory module in FIG. 6A, including a first active cooling device disposed on the memory chips;

FIG. 6C is a cross-sectional side view of a second region of the memory module in FIG. 6A, including a second active cooling device disposed on analog components of the memory module; and

FIG. 7 is an illustration of a computer processing system including a processor and an exemplary memory module, including active cooling devices disposed on a substrate including memory chips.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic, and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Aspects disclosed herein include memory modules, including active cooling devices. Related methods of active cooling in a memory module are also disclosed. Memory modules are employed in computer processing systems to store data that may be accessed by or produced in a processing circuit. The data in a memory module is stored in memory chips that are coupled to a surface of one or more substrates, referred to as cards or boards. The memory chips may each contain large numbers of storage cells that consume power during normal operation, generating heat in the memory chips and causing temperatures to increase. As the temperatures increase, leakage currents can increase in the memory chips and performance of the memory chips can decrease. In exemplary aspects disclosed herein, a memory module includes memory chips disposed on a substrate and an active cooling device disposed on the substrate to increase the rate at which heat is dissipated to reduce or maintain temperatures and thereby save power and improve performance. In some examples, the active cooling device is disposed on a side of a memory chip opposite to the card in the memory module to improve cooling of the memory chips. In some examples, the active cooling device is a thermoelectric device.

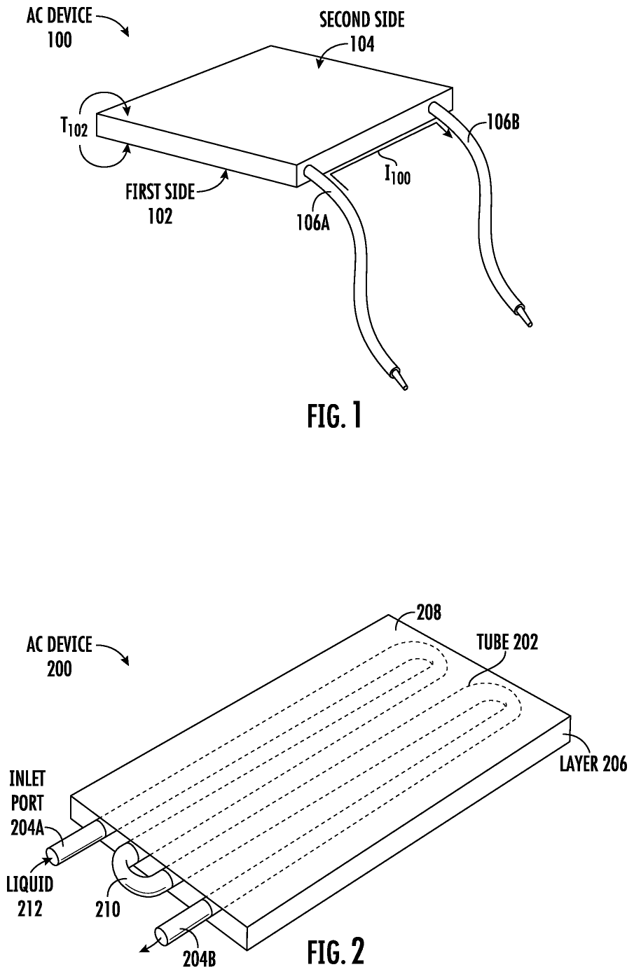

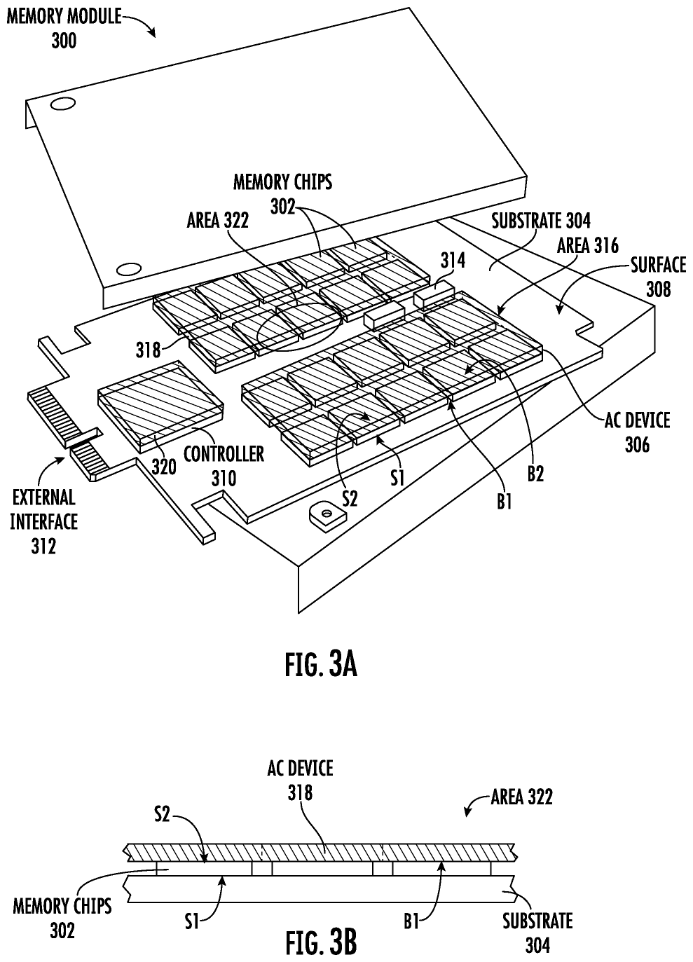

Before exemplary memory modules 300, 500, 600, and 700, including active cooling (AC) devices are described in detail with reference to FIGS. 3A, 3B, 4A, 4B, 5A-5C, and 6A-6C, below, examples of active cooling devices 100 and 200 are first described with reference to FIGS. 1 and 2.

FIG. 1 is an illustration of an AC device 100, which is a thermoelectric cooling device in this example. Thermoelectric cooling devices employ the Peltier effect in which heat is transferred from a first, cold surface 102 of the device to a second, hot surface 104, opposite to the first surface 102, depending on a direction of a current in the device. A thermoelectric device may also be called a Peltier device or a solid-state heat pump. As the Peltier effect is well documented, further details of operation are not provided here.

The AC device 100 includes terminals 106A and 106B. A voltage V₁₀₀ applied between the terminals 106A and 106B causes a current I₁₀₀ to flow in the AC device 100. The current I₁₀₀ can move heat from the first surface 102 of the AC device 100 to the second surface 104. The amount of heat transferred may be directly related to the current I₁₀₀. In response to the current T₁₀₀, a temperature difference T₁₀₂ is created between the first surface 102 and the second surface 104 due to heat energy being moved from the first surface 102 to the second surface 104. Thus, if the first surface 102 is positioned on or against a surface of another structure and thermally coupled to such structure, the surface of the structure may be cooled by conduction of heat from the surface to the first surface 102 and then to the second surface 104, where it is dissipated. The first surface 102 may be referred to as the cold side and the second surface 104 may be referred to as the hot side.

FIG. 2 is a second example of an AC device 200, specifically a liquid cooling device in this example. The AC device 200 includes a tube 202 having an inlet port 204A and an outlet port 204B configured for liquid flow through the tube 202. The tube 202 in this example is embedded in a material or layer 206, which may be made of a thermally conductive material 208 to improve heat transfer. The tube 202 may also be formed of a thermally conductive material 210, such as a metal with higher thermal conductivity, such as copper, for example. In this context, the term “thermally conductive” indicates a material has a thermal conductivity of at least 1.0 (watts per metre per degree Celsius (W/m/° C.)). The inlet port 204A may be coupled to a pump (not shown) by way of plumbing that provides a source of cooled or chilled liquid 212, such as water or another liquid coolant. Pumping a chilled liquid 212 through the tube 202 can cool the layer 206. When the liquid 212 is cooler than the warmer layer 206, there is a temperature gradient that causes heat from the layer 206 to be conducted through the tube 202 and into the liquid 212 in the tube 202, transferring heat from the layer 206 into the liquid 212. The outlet port 204B may be coupled through plumbing to a drain or to a reservoir where the liquid 212 can be cooled again by another device or method before it is provided again to the inlet port 204A. As the liquid 212 is carried away (through the outlet port 204B) and replaced by new, cooler liquid 212 (e.g., through the inlet port 204A), the temperature of the layer 206 is reduced. A cryogenic cooler is one example of an active liquid cooling device.

FIG. 3A is an illustration of the exemplary memory module 300 including memory chips 302 disposed on a substrate 304. The memory module 300 includes an AC device 306 also disposed on the substrate 304 to improve heat dissipation from heat generating components of the memory module 300. The memory module 300 is configured to store data to be accessed by or provided by a processing circuit (not shown). Each of the memory chips 302 can store a portion of the data stored in the memory module 300. In some examples, the memory module 300 may be a solid-state drive (SSD) device having an E3.S form factor, as known to persons of skill in the art. However, the memory module 300 is not limited in this regard. The memory chips 302 in the memory module 300 can be any type of memory chip including non-volatile memory, including but not limited to static random access memory (RAM) (SRAM), dynamic RAM, ferromagnetic RAM (FeRAM), and NAND memory devices, for example.

The AC device 306 may comprise a thermoelectric device (e.g., Peltier device) corresponding to the AC device 100 in FIG. 1 or a liquid cooling device corresponding to the AC device 200 in FIG. 2. Although not shown, it should be understood that appropriate plumbing or electrical connections corresponding to the type of AC device 306 employed in the memory module 300 would be provided in a computer processing system that includes the memory module 300. In the example of a thermoelectric AC device 306, electrical power may be provided to the AC device 306 at a power supply voltage through electrical contacts (not shown), which may be on a surface 308 of the substrate 304. The substrate 304 may be a laminated card or board with the memory chips 302 coupled to the surface 308. The substrate 304 may include electrical wires or traces (not shown) disposed on the surface 308 or in layers (not shown) of a laminate of the substrate 304. Alternatively, the The memory module 300 also includes a controller circuit 310 (“controller 310”) disposed on the surface 308 and also includes an external interface 312 for coupling the memory module 300 to an external circuit. In a computing system, the controller 310 controls memory access operations of the memory module 300, such as receiving write transactions via the external interface 312 and writing data into the memory chips 302. The controller 310 also receives read transactions via the external interface 312, reads data from the memory chips 302, and provides the data to the external interface 312.

The electrical wires of the substrate 304 are provided to couple the controller 310 to the memory chips 302 and also to the external interface 312. The external interface 312 may be plugged into a memory slot on a board in a computer system or computing device, for example. In some examples, the external interface 312 may provide a serial interface to an external memory controller, bus controller, processor or processing circuit. In this regard, the memory module 300 may comprise a serial attached memory. In some examples, the interface 312 provides a parallel bus interface. The external interface 312 also couples the memory module 300 to a power supply voltage that is provided to the memory chips 302 and the memory controller 310 by a power distribution network (not shown) on the substrate 304. In addition, the memory module 300 may include rechargeable power storage devices 314 coupled to a power distribution network. Examples of the rechargeable power storage devices 314 include capacitors, batteries, and hybrid devices (e.g., “hybrid capacitors” or “supercaps”). As an example, hybrid capacitors (“hybrid caps”) may be employed for non-volatile memory (NVM) in certain examples of memory modules, such as dual in-line memory modules (DIMMs) and compute express link (CXL) memory modules (e.g., memory modules having a CXL interface). In the present example, the rechargeable power storage devices 314 will be referred to as capacitors 314.

When the memory module 300 is employed in a computer processing system, data in the memory chips 302 may be accessed frequently by a processing circuit (not shown). As data is read from and written to the memory chips 302, at least some of the transistor circuits in the memory chips 302 change state, being charged and discharged in successive cycles of a system clock. These state changes consume power and cause heat to be generated in the memory chips 302, which raises their temperature. Consequently, the temperature of the transistor circuits in the memory chips 302 increases and leakage currents may increase, which causes the memory circuits to discharge faster than normal. As a result, for some types of memory chips 302, it becomes necessary to increase the frequency of refresh cycles, to maintain the data stored therein, consuming even more power.

Similarly, the controller 310 includes transistor circuits that are switching in response to every memory access operation, causing the controller 310 to also consume power, generate heat, and increase in temperature. The memory module 300 may also be enclosed in a housing with other components that generate heat.

In this regard, the memory module 300 includes the AC device 306 disposed on the substrate 304. In some examples, the AC device 306 is disposed on the memory chips 302, which are on the substrate 304. Thus, the AC device 306 may be disposed directly on the memory chips 302 and indirectly on the substrate 304 in some examples. Each of the memory chips 302 has a first side S1 facing the surface 308 of the substrate 304. On the first side S1 of each of the memory chips 302, there may be pins, contacts, and/or solder balls that electrically and mechanically couple the memory chips 302 to the surface 308. The memory chips 302 also have a second side S2 opposite to the substrate 304. The AC device 306 may be disposed directly on the second side S2 of the memory chips 302. Alternatively, the AC device 306 may be disposed indirectly on the second side S2 of the memory chips 302. In this context, the term “disposed indirectly on” may indicate that another material or object is disposed between the AC device 306 and the second side S2 of the memory chips 302. In some examples, the memory module 300 may include a thermal paste (not shown) between the second side S2 of the memory chips 302 and the AC device 306. In addition, or in the alternative, the memory module 300 may include a thermally conductive material comprising a solid layer between the memory chips 302 and the AC device 306. Whether the memory module 300 includes a thermal paste or a solid thermally conductive layer between the AC device 306 and the memory chips 302, or the AC device 306 is disposed directly on the memory chips 302, a surface B1 of the AC device 306 is thermally coupled to the second side S2 of one or more of the memory chips 302.

As shown in FIG. 3A, the memory chips 302 may be disposed on the surface 308 of the substrate 304 in a rectangular area 316. Thus, the AC device 306 may extend over the rectangular area 316 to cool each of the memory chips 302 in the rectangular area 316.

In additional or alternative examples, the memory module 300 may include an AC device 318 disposed on and/or thermally coupled to the controller 310. The AC device 318 being disposed on the controller 310 may include being disposed directly on the controller 310 (e.g., in direct contact) or disposed indirectly on the controller 310 with an intervening thermal paste and/or another material (e.g., a solid layer). For example, a thermal interface material (TIM) may be included between the AC device 318 and the controller 310. Additionally, a TIM may be used between any instance of the AC device 318 and the heat-generating device on which it is disposed to thermally couple the AC device 318 to the heat-generating device (e.g., controller 310). Herein, the term “thermally coupled” may also be defined as having a conductive path through materials with higher thermal conductivity than air.

In further examples, the memory module 300 may include an AC device 320 disposed on and/or thermally coupled to the capacitors 314. The lifespan of some capacitors may be significantly reduced by increased temperatures. Thus, the AC device 320 is disposed on the capacitors 314 directly or indirectly, as discussed above with regard to the AC devices 306 and 318, to reduce temperatures of the capacitors 314 during operation.

Although the memory module 300 includes AC devices 306, 318, and 320, in some examples a single AC device (not shown) may be disposed over multiple components of different types. For example, an AC device may be disposed over the memory chips 302 and one or both of the controller 310 and the capacitors 314, or over just the controller 310 and the capacitors 314. Other components on the memory module 300 may also be cooled by an AC device.

The AC devices 306, 318, and 320 are referred to as “active cooling” devices because they are configured to actively remove heat from the second side S2 of the memory chips 302 and from the controller 310, respectively. In this context, “actively removing heat” includes using a flow of electricity or fluid to reduce a temperature of the first side B1 of the AC device 306 that is thermally coupled to the memory chips 302 or controller 310, allowing more heat to be removed from the memory chips 302 and/or the controller 310 than is possible by passive conduction through an inactive layer or device, such as a heat sink, that does not employ electric or fluid flow. Thus, in such examples, the heat sink may be disposed on the substrate 304 and the AC device 306 is disposed on the heat sink. In some examples, the memory module 300 may include a heat sink disposed on a second side B2, opposite to the first side B1, of the AC device 306. The second side B2 of the AC device 306 corresponds to the second, hot surface 104 of the AC device 100 in FIG. 1.

A region 322 of the memory module 300 is shown in cross-section in FIG. 3B. FIG. 3B shows an example in which the first sides S1 of the memory chips 302 are disposed on the surface 308 of the substrate 304 and the AC device 318 is disposed directly on (e.g., in direct contact with) the second sides S2 of the memory chips 302 to actively cool the memory chips 302. Components such as the memory chips 302 and the controller 310 of the memory module 300 can be cooled by the AC devices 306, 318, and 320, allowing the memory module 300 to operate at a reduced temperature for higher performance and without the negative effects of exposure to higher temperatures. In the capacitors 314, negative effects caused by high temperatures include a reduction in capacitance and increased equivalent series resistance (ESR), resulting in lower energy output and indicating an end-of-life condition for such components.

FIG. 3B is a cross-sectional side view of a region of the memory module 300 in FIG. 3A, showing the first side S1 of the memory chips 302 disposed on the surface 308 of the substrate 304, and showing the first side B1 of the AC device 318 disposed on the second side S2 of the memory chips 302. In this example, the AC device 318 is disposed directly on the second side S2 of the memory chips 302 but it not limited in this regard, as discussed above.

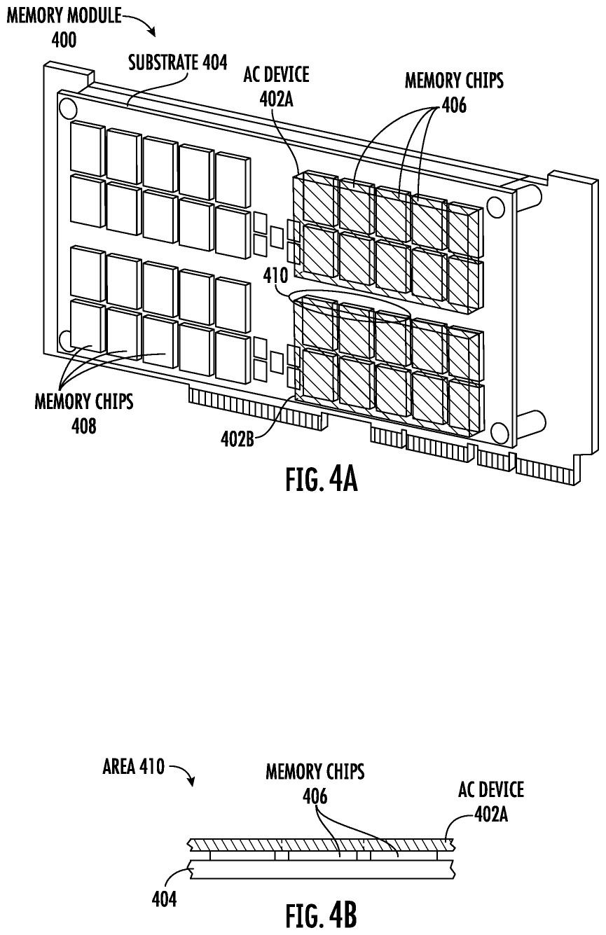

FIG. 4A is a second example of an exemplary memory module 400 comprising AC devices 402A and 402B disposed on a substrate 404 including memory chips 406. The memory module 400 is an example having an add-in-card (AIC) form factor. In this example, the AC devices 402A and 402B are disposed on the memory chips 406 to improve heat dissipation to reduce a temperature of the memory chips 406. In this example, memory chips 408 are also disposed on the substrate 404 and may have a higher operating temperature than the memory chips 406 due to the absence of AC devices disposed thereon.

The AC devices 402A and 402B may be either thermoelectric devices corresponding to the AC device 100 in FIG. 1, or liquid cooling devices corresponding to the AC device 200 in FIG. 2. The AC devices 402A and 402B may be disposed on the memory chips 406 in a manner similar to the AC device 306 disposed on the memory chips 302 described above with reference to FIG. 3A. In other words, the AC devices 402A and 402B may be disposed directly on or indirectly on the memory chips 406 to be thermally coupled to the memory chips 406. FIG. 4B is a cross-sectional view of an area 410 of the memory module 400 in FIG. 4A illustrating the AC device 402A disposed on the memory chips 406, which are disposed on the substrate 404. The memory chips 406 cooled by the same AC device 402A may be, in an alternative example, cooled by multiple smaller AC devices similar to AC device 402A.

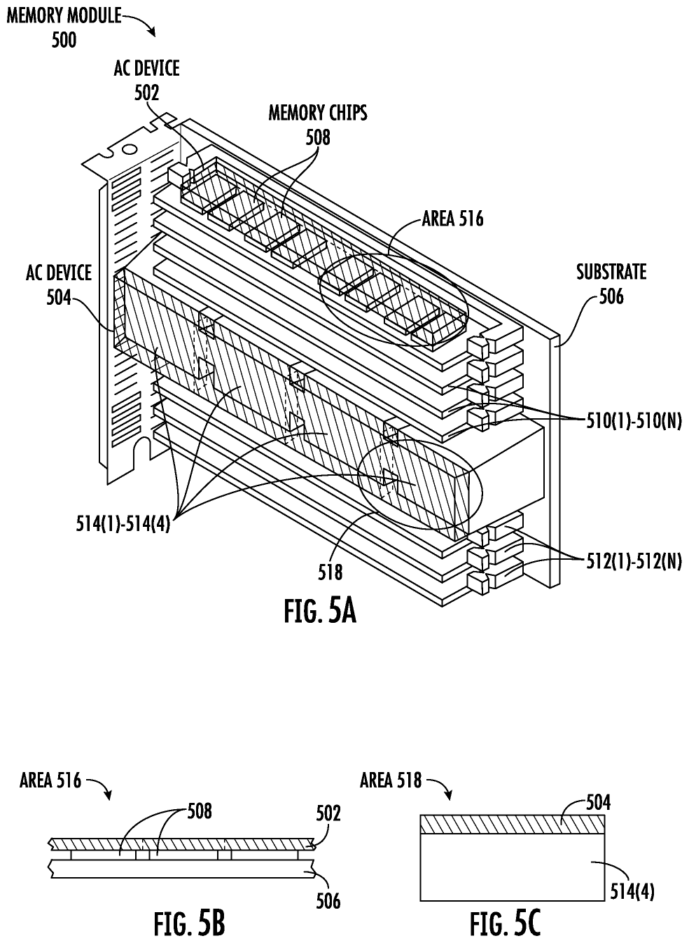

FIG. 5A is a third example of an exemplary memory module 500 comprising AC devices 502 and 504 disposed on a substrate 506 that includes memory chips 508. The memory module 500 is another example of an add-in-card (AIC) form factor having a plurality of smaller substrates 510(1)-510(N) disposed in slots 512(1)-512(N) on the substrate 506. In this example, the AC devices 502 is disposed on the memory chips 508. The memory module 500 also includes component structures 514(1)-514(4), which may be capacitors or enclosures containing heat generating components. Alternatively, the component structures 514(1)-514(4) may be heat sinks disposed on heat generating components (not shown) disposed on the substrate 506. As another example, the component structures 514(1)-514(X) may be power management circuits implemented directly on the substrate 506. Power management circuits receive power from an external source and provide current and voltage according to the needs of the memory chips 508 and other devices. In any of such examples, all of which may be heat-generating devices, the AC device 504 (provided as a single device or multiple devices) is disposed on the structures 514(1)-514(4), directly or indirectly, to improve heat dissipation. In this example, each of the AC devices 502 and 504 may be either thermoelectric devices corresponding to the AC device 100 in FIG. 1, or liquid cooling devices corresponding to the AC device 200 in FIG. 2. The AC devices 502 and 504 may be disposed on the memory chips 508 and/or on the component structures 514(1)-514(4) in the manners described above with reference to FIG. 3A. For example, the AC devices 502 and 504 may be disposed directly on or indirectly on the memory chips 508 and the component structures 514(1)-514(4). Although not shown, each of the smaller substrates 510(1)-510(N) may include memory chips and corresponding AC devices as described above provided thereon.

FIG. 5B is a cross-sectional view of an area 516 of the memory module 500 in FIG. 5A illustrating the AC device 502 disposed on the memory chips 508. FIG. 5C is a cross-sectional view of an area 518 of the memory module 500 in FIG. 5A illustrating the AC device 504 disposed on the component structures 514(1)-514(4).

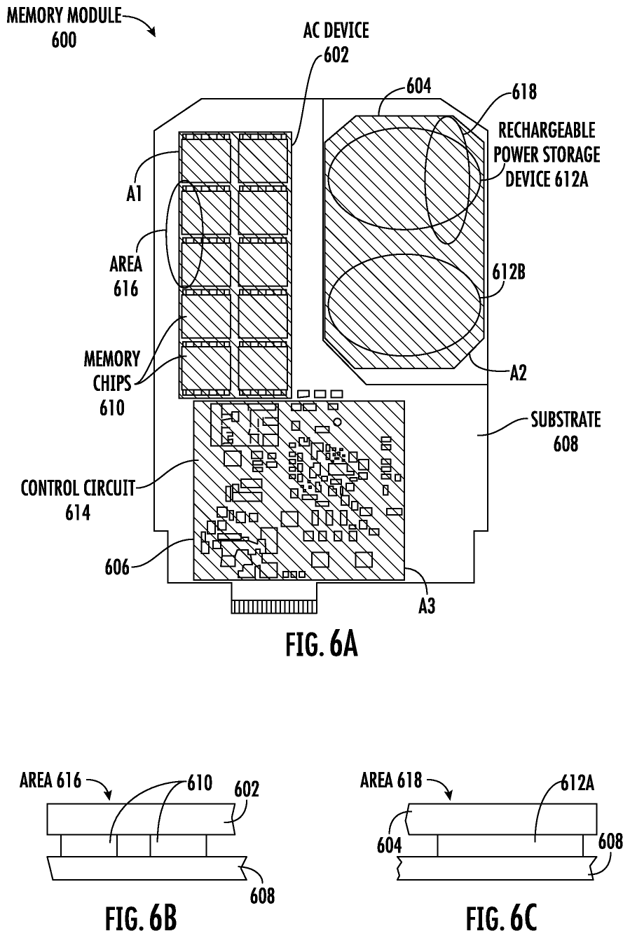

FIG. 6A is a fourth example of an exemplary memory module 600 comprising AC devices 602, 604, and 606 disposed on a substrate 608 that includes memory chips 610. The memory module 600 may have an E3.S type form factor with a CXL interface. The memory module 600 includes the memory chips 610 in a first area A1 and rechargeable power storage devices 612A and 612B (e.g., capacitors, hybrid capacitors, batteries) disposed in a second area A2 on the substrate 608. The memory module 600 also includes control circuit 614 disposed in a third area A3 of the substrate 608. In this example, the AC device 602 is disposed in the area A1 on the memory chips 610. The AC device 604 is disposed in the area A2 on the rechargeable power storage devices 612A and 612B. The AC device 606 is disposed in the area A3 on the control circuit 614. In other examples, the memory module 600 may include any one or any two of the AC devices 602, 604, and 606 shown in this example. Any of the AC devices 602 and 604 may alternatively be replaced by two or more AC devices each corresponding to one or more of the memory chips 610 or one of the rechargeable power storage devices 612A and 612B.

The AC devices 602, 604, and 606 may be individually controlled. As an example, the memory module 600 may include temperature sensors (not shown) in each of the areas A1, A2, and A3 that are used to determine whether the AC devices 602, 604, and 606 need to be activated. In addition, the cooling (heat transfer) capabilities of the AC devices 602, 604, and 606 may be set to different cooling levels in response to temperatures within predetermined ranges, whether the AC devices 602, 604, and 606 are thermoelectric devices corresponding to the AC device 100 in FIG. 1, or liquid cooling devices corresponding to the AC device 200 in FIG. 2. For example, in AC devices that are thermoelectric devices, the current may be increased or decreased as needed to achieve an acceptable cooling effect. In AC devices that are fluid cooling devices, the rate of fluid flow and/or the temperature of the fluid entering the fluid cooling device can be adjusted according to the temperature in the area employing the AC device.

The AC devices 602, 604, and 606 may be disposed directly on or indirectly on the memory chips 610, the rechargeable power storage devices 612A and 612B, and the control circuit 614 in the manners described above with reference to FIG. 3A. FIG. 6B is a cross-sectional view of an area 616 of the memory module 600 in FIG. 6A illustrating the AC device 602 disposed on the memory chips 610. FIG. 6C is a cross-sectional view of an area 618 of the memory module 600 in FIG. 6A illustrating the AC device 604 disposed on the rechargeable power storage devices 612A and 612B.

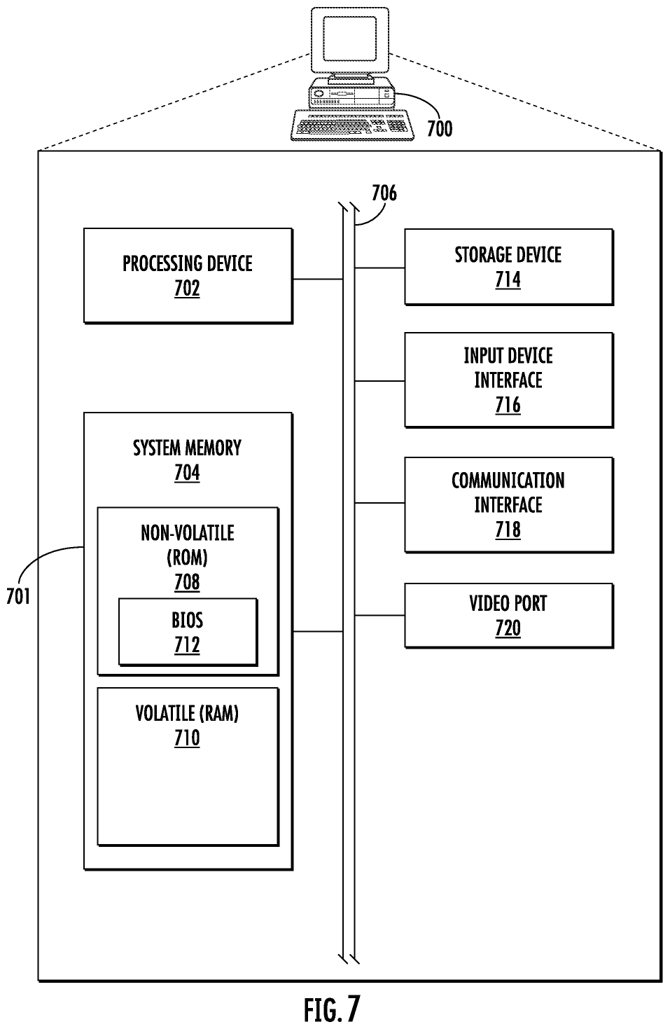

FIG. 7 is an exemplary computer system 700 that is one example of a computer processing system including at least one memory module 701. The exemplary computer system 700 in this embodiment includes a processing device 702 or processor, a system memory 704, and a system bus 706. The processing device 702 represents one or more commercially available or proprietary general-purpose processing devices, such as a microprocessor, central processing unit (CPU), or the like. More particularly, the processing device 702 may be a complex instruction set computing (CISC) microprocessor, a reduced instruction set computing (RISC) microprocessor, a very long instruction word (VLIW) microprocessor, a processor implementing other instruction sets, or other processors implementing a combination of instruction sets. The processing device 702 is configured to execute processing logic instructions for performing the operations and steps discussed herein.

In this regard, the various illustrative logical blocks, modules, and circuits described in connection with the embodiments disclosed herein may be implemented or performed with the processing device 702, which may be a microprocessor, field programmable gate array (FPGA), a digital signal processor (DSP), an application-specific integrated circuit (ASIC), or other programmable logic device, a discrete gate or transistor logic, discrete hardware components, or any combination thereof designed to perform the functions described herein. Furthermore, the processing device 702 may be a microprocessor, or may be any conventional processor, controller, microcontroller, or state machine. The processing device 702 may also be implemented as a combination of computing devices (e.g., a combination of a DSP and a microprocessor, a plurality of microprocessors, one or more microprocessors in conjunction with a DSP core, or any other such configuration).

The system memory 704 may include the memory module 701, which may be any of the memory modules 300, 400, 500, and 600 described above with reference to FIGS. 3A-6C. The system memory 704 including the memory module 701 may further include non-volatile memory 708 and volatile memory 710. The non-volatile memory 708 may include read-only memory (ROM), erasable programmable read-only memory (EPROM), electrically erasable programmable read-only memory (EEPROM), and the like. The volatile memory 710 generally includes RAM (e.g., DRAM, such as SDRAM). A basic input/output system (BIOS) 712 may be stored in the non-volatile memory 708 and can include the basic routines that help to transfer information between elements within the computer system 700.

The system bus 706 provides an interface for system components including, but not limited to, the system memory 704 and the processing device 702. The system bus 706 may be any of several types of bus structures that may further interconnect to a memory bus (with or without a memory controller), a peripheral bus, and/or a local bus using any of a variety of commercially available bus architectures.

The computer system 700 may further include or be coupled to a non-transitory computer-readable storage medium, such as a storage device 714, which may represent an internal or external hard disk drive (HDD), flash memory, or the like. The storage device 714 and other drives associated with computer-readable media and computer-usable media may provide non-volatile storage of data, data structures, computer-executable instructions, and the like. The storage device 714 may also be or include any of the memory modules 300, 400, 500, and 600 described above with reference to FIGS. 3A-6C. The computer system 700 may also include input device interface 716, communication interface 718, and video port 720, for example.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A memory module configured to store data, the memory module comprising:
at least one substrate;
one or more memory chips disposed on the at least one substrate, each memory chip configured to store a portion of the data; and
an active cooling device disposed on the at least one substrate.

2. The memory module of claim 1, wherein:
each memory chip of the one or more memory chips comprises a first side facing the at least one substrate and a second side opposite to the at least one substrate; and
the active cooling device is disposed on the second side of the one or more memory chips.

3. The memory module of claim 1, wherein the one or more memory chips are disposed on a rectangular area of the substrate and the active cooling device extends over the rectangular area.

4. The memory module of claim 1, further comprising one or more rechargeable power storage devices disposed on the substrate, wherein the active cooling device is disposed on the one or more rechargeable power storage devices.

5. The memory module of claim 2, wherein the active cooling device comprises a first surface thermally coupled to the second side of the one or more memory chips.

6. The memory module of claim 5, wherein the first surface of the active cooling device is in direct contact with the second side of the one or more memory chips.

7. The memory module of claim 2, wherein the active cooling device is configured to actively remove heat from the second side of the one or more memory chips.

8. The memory module of claim 5, wherein a thermally conductive material is disposed between the second side of the one or more memory chips and the first surface of the active cooling device.

9. The memory module of claim 8, wherein the thermally conductive material comprises a paste.

10. The memory module of claim 1, wherein the active cooling device comprises a thermoelectric cooling device.

11. The memory device of claim 10, wherein the substrate further comprises electrical contacts configured to couple the active cooling device to a power supply voltage.

12. The memory module of claim 5, wherein the active cooling device further comprises:
a second surface opposite to the first surface; and
a heat sink disposed on the second surface.

13. The memory module of claim 1, wherein the active cooling device comprises a liquid cooling device comprising a tube comprising an inlet port and an outlet port for liquid flow.

14. The memory module of claim 1, further comprising a controller circuit disposed on the substrate, wherein the active cooling device is disposed on the controller circuit.

15. The memory module of claim 1, further comprising a serial attached memory.

16. The memory module of claim 1, further comprising a CXL memory module.

17. The memory module of claim 1, further comprising an add-in-card (AIC) form factor.

18. The memory module of claim 1, further comprising a solid-state device (SSD) memory module.

19. The memory module of claim 1, further comprising a dual inline memory module (DIMM).

20. The memory module of claim 1, further comprising one or more rechargeable power management devices disposed on the substrate, wherein the active cooling device is disposed on the one or more power management devices.

21. A computer processing system comprising:
a processor circuit configured to process data; and
a memory module configured to store the data, the memory module comprising:
at least one substrate;
one or more memory chips disposed on the at least one substrate, each configured to store a portion of the data; and
an active cooling device disposed on the at least one substrate.

22. The computer processing system of claim 21, wherein the active cooling device is disposed on one or more of the memory chips.
